(19) United States
(12) Patent Application Publication
(10) Pub. No.: US 2026/0104455 A1
(43) Pub. Date: Apr. 16, 2026

(54) CLOCK CONTROL CIRCUIT AND METHOD

(71) Applicant: Realtek Semiconductor Corporation, Hsinchu (TW)

(72) Inventors: Yu-Ting LI, Hsinchu (TW); Pei-Ying HSUEH, Hsinchu (TW); Ying-Yen CHEN, Hsinchu (TW)

(21) Appl. No.: 19/302,111

(22) Filed: Aug. 18, 2025

(30) Foreign Application Priority Data
Oct. 11, 2024 (TW) 113138798

(51) Int. Cl. G01R 31/3185

(52) U.S. Cl. CPC G01R 31/318555; G01R 31/318544; G01R 31/318552

(57) ABSTRACT

A clock control circuit for a circuitry, including a scan flip-flop circuit, an at-speed domain and a timing exception domain, includes a first gate control circuit, a first gate circuit, a second gate control circuit and a second gate circuit. The first gate circuit is controlled by a first control signal output by the first gate control circuit, a scan enable signal and a scan mode signal to block or output a clock signal to the scan flip-flop circuit. The second gate circuit is controlled by a second control signal output by the second gate control circuit to block or output an output signal of the scan flip-flop circuit to the timing exception domain. When the scan mode signal has a first logic value, the second control signal switches between the first logic value and a second logic value according to a test pattern.

### CROSS-REFERENCE TO RELATED APPLICATION

This application claims priority to Taiwan Application Serial Number 113138798, filed Oct. 11, 2024, which is herein incorporated by reference in its entirety.

### BACKGROUND

### Field of Invention

The disclosure relates to a clock control circuit and method. More particularly, the disclosure relates to a clock control circuit and method for a scan flip-flop circuit.

### Description of Related Art

In the existing scan chain test technology, under certain tests (e.g., transition delay fault test), some timing exception paths (e.g., error paths, multi-cycle paths, etc.) in the circuit to be tested often generate unknown data values due to receiving the transition data values, which increases the number of test patterns for testing the circuit to be tested. This increase of the number of test patterns further increases the test time and cost of the circuit under test. Therefore, it is necessary to solve this problem.

### SUMMARY

The disclosure provides a clock control circuit for controlling a circuitry, wherein the circuitry includes one or more scan flip-flop circuit, an at-speed domain and a timing exception domain. The scan flip-flop circuit is configured to output data to the at-speed domain and the timing exception domain. The clock control circuit includes a first gate control circuit, a first gate circuit, a second gate control circuit and a second gate circuit. The first gate control is configured to be controlled by a scan mode signal and configured to output a first control signal. The first gate circuit is coupled to the first gate control circuit and the scan flip-flop circuit, and is configured to be controlled by the first control signal, a scan enable signal and the scan mode signal, and configured to block or output a clock signal to the scan flip-flop circuit. The second gate control circuit is coupled to the first gate control circuit, and is configured to be controlled by the scan mode signal and output a second control signal, wherein when the scan mode signal has a first logic value, the second control signal switches between the first logic value and a second logic value different from the first logic value according to a test pattern for testing the circuitry. The second gate circuit is coupled to the scan flip-flop circuit, the second gate control circuit and the timing exception domain, and is configured to be controlled by the second control signal, and configured to block or output an output signal of the scan flip-flop circuit to the timing exception domain.

The disclosure also provides a clock control method for a circuitry. The circuitry includes one or more scan flip-flop circuit, an at-speed domain and a timing exception domain. The scan flip-flop circuit is configured to output data to the at-speed domain and the timing exception domain. The clock control method includes: by a first gate control circuit, outputting a first control signal according to the control of a scan mode signal; by a first gate circuit coupled to the first gate control circuit and the scan flip-flop circuit, blocking or outputting a clock signal to the scan flip-flop circuit according to the first control signal, a scan enable signal and the scan mode signal; by a second gate control circuit coupled to the first gate control circuit, outputting a second control signal according to the control of the scan mode signal, wherein when the circuitry operates in a capture phase of a scan test, the second control signal switches between a first logic value and a second logic value according to a test pattern for testing the circuitry; and, by a second gate circuit coupled to the scan flip-flop circuit, the second gate control circuit and the timing exception domain, blocking or outputting an output signal of the scan flip-flop circuit to the timing exception domain according to the control of the second control signal.

In summary, when the circuitry operates in the capture phase of the scan test, the clock control circuit always provides fixed data value to the timing exception domain. In this way, the transition delay fault test of the circuitry will not be affected by unknown data values, which can avoid the increases of the number of test patterns, the test time and the test costs. In addition, under the stuck-at fault test, since the second control signal received by the second gate circuit switches between the first logic value and the second logic value, a stuck-at-0 fault test of the second gate circuit can be performed to the second gate circuit in addition to the stuck-at-1 fault test to the second gate circuit. Thereby, the test coverage of the stuck-at fault test will be greatly improved.

### BRIEF DESCRIPTION OF THE DRAWINGS

FIG. 1 is a simplified functional block diagram of a circuitry according to the relevant technology.

FIG. 2 is a block diagram of a clock control circuit applied to the circuitry in FIG. 1 according to some embodiments of the present disclosure.

FIG. 3 is a schematic diagram of the clock control circuit in FIG. 2.

FIG. 4 is a flow chart of the clock control method according to some embodiments of the present disclosure.

FIG. 5A is a schematic diagram of the operation of the clock control circuit of the circuitry in the capture phase of the stuck-at fault test or the transition delay fault test according to some embodiments of the present disclosure.

FIG. 5B is a schematic diagram of the operation of the clock control circuit of the circuitry in the capture phase of the stuck-at fault test or the transition delay fault test according to some embodiments of the present disclosure.

FIG. 6 is a schematic diagram of the operation of the clock control circuit in the circuitry in the functional mode according to some embodiments of the present disclosure.

FIG. 7 is a block diagram of another clock control circuit applied to the circuitry in FIG. 1 according to some embodiments of the present disclosure.

FIG. 8 is a schematic diagram of the operation of the clock control circuit of the circuitry in the capture phase of the of the stuck-at fault test according to some embodiments of the present disclosure.

### DETAILED DESCRIPTION

The following describes embodiments in detail with reference to the drawings. However, the specific embodiments described are only intended to illustrate the present disclosure, rather than to define the present disclosure, and the description on structure operations is not adopted to limit the order in which the structure operations are performed; and any device with an equal effect resulting from the recombination of components of the structure falls within the scope of the present disclosure.

Terms used throughout the Description and the Claims of the present disclosure, unless otherwise specified, generally have the ordinary meaning of each term used in the art, in the present disclosure and in special contents.

The term “coupling” or “connecting” used herein may refer to a direct physical or electrical contact between two or more components, or to an indirect physical or electrical contact between two or more components, or to an interoperation or action of two or more components.

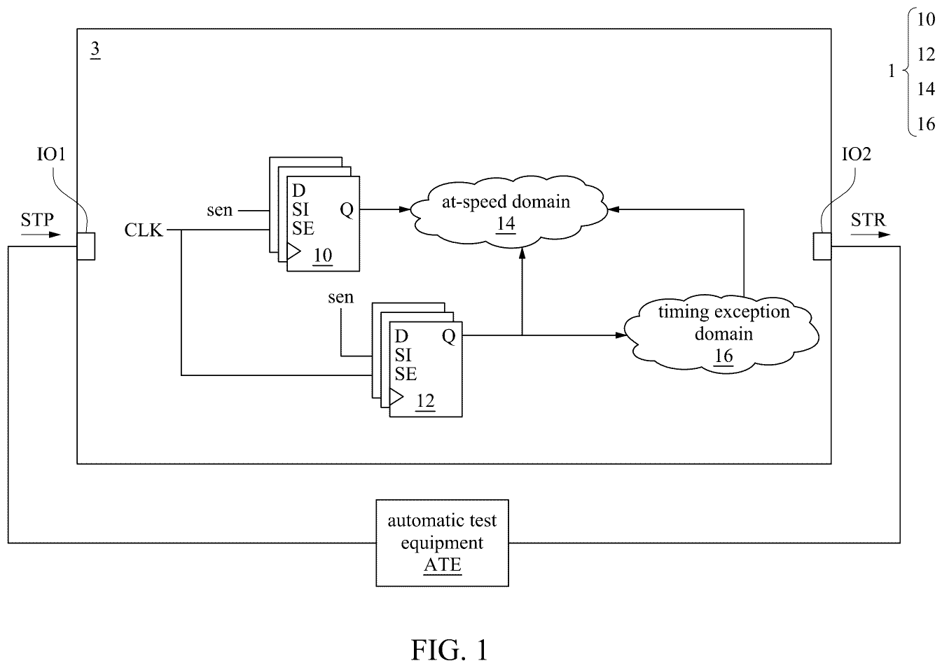

Please refer to FIG. 1, which is a simplified functional block diagram of a circuitry 1 according to the relevant technology. As shown in FIG. 1, the circuitry 1 comprises one or more scan flip-flop circuits 10, one or more scan flip-flop circuits 12, an at-speed domain 14, and a timing exception domain 16. The circuitry 1 can be configured on a chip 3, and an automatic test equipment ATE can test the circuitry 1 via the chip 3. In particular, the at-speed domain 14 and the timing exception domain 16 respectively comprise a combinational logic circuit formed by various logic gates, and the scan flip-flop circuit 10 and the scan flip-flop circuit 12 respectively are a sequential logic circuit different from the combinational logic circuit.

In the related technology of FIG. 1, each of the scan flip-flop circuit 10 and 12 has a first data input terminal D, a second data input terminal SI, an input enable terminal SE and a data output terminal Q, where the input enable terminal SE is configured to receive a scan enable signal sen. In addition, each of the scan flip-flop circuit 10 and the scan flip-flop circuit 12 is configured to receive a clock signal CLK via a clock input terminal (represented by a “>” in the figures). Accordingly, the scan flip-flop circuit 10 and the scan flip-flop circuit 12 respectively are configured to temporarily store the data received at the first data input terminal D or the second data input terminal SI according to the scan enable signal sen and the clock signal CLK. For example, the scan flip-flop circuit 10 and scan flip-flop circuit 12 respectively respond to the triggering of at least one pulse in the clock signal CLK to temporarily store the data received at the second data input terminal SI when the scan enable signal sen has a first logic value (e.g., logic “1”). For example, the scan flip-flop circuit 10 and scan flip-flop circuit 12 respectively respond to the triggering of at least one pulse in the clock signal CLK to temporarily store the data received at the first data input terminal D when the scan enable signal sen has a second logic value (e.g., logic “0”).

As mentioned above, the data output terminal Q of the scan flip-flop circuit 10 is coupled to the at-speed domain 14 to output the temporarily stored data to the at-speed domain 14. The data output terminal Q of the scan flip-flop circuit 12 is coupled to the at-speed domain 14 and the timing exception domain 16 to output the temporarily stored data to the at-speed domain 14 and the timing exception domain 16. The timing exception domain 16 is coupled to the at-speed domain 14 and receives the data output by the scan flip-flop circuit 12 to generate data to the at-speed domain 14. In addition, the at-speed domain 14 receives the data output by the scan flip-flop circuit 10, the data output by the scan flip-flop circuit 12 and the data output by the timing exception domain 16, to generate data.

It should be understood that the connection structure of the circuitry 1 in FIG. 1 is shown for the illustrative purposes only but not for limitations. For example, the first data input terminal D is usually coupled to a data output terminal of at least one combinational logic circuit in the circuitry 1. The second data input SI is usually coupled to a data output terminal of at least one scan flip-flop circuit in the circuitry 1. The data output terminal Q is usually coupled to a data input terminal of at least one combinational logic circuit and/or a second data input terminal of at least one scan flip-flop circuit in the circuitry 1. Accordingly, a plurality of sequential logic circuits connected in series form a scan chain path in the circuitry 1. In addition, the data output terminal of the at-speed domain 14 can also be coupled to a first data input terminal of at least one scan flip-flop circuit in the circuitry 1.

As also shown in FIG. 1, the automatic test equipment ATE is configured to generate a predetermined test pattern STP. In the relevant technology, the test pattern STP is configured to test the circuitry 1 and can be a data sequence. Specifically, the test pattern STP may comprise a predetermined number of data values (e.g., logic “0”, logic “1”, etc.) in an arrangement which can be predetermined by the automatic test equipment ATE according to the test to be performed on the circuitry 1.

In the relevant technology, the automatic test equipment ATE can input the test pattern STP to the circuitry 1 via a scan input terminal IO1 on the chip 3 to perform the scan test the circuitry 1 via the scan chain path. In addition, the automatic test equipment ATE can receive a test output STR from circuitry 1 via a scan output terminal 102 on the chip 3 to obtain the operating status of the circuitry 1. In general, the execution process of the scan test includes at least a shift phase and a capture phase, which are well known to those skilled in the art to which this disclosure belongs. Therefore, the shift phase and the capture phase will be briefly explained in the following paragraphs with the structure of FIG. 1 as an example.

In the shift phase, the scan enable signal sen has a first logic value. In response to the triggering of at least one pulse in the clock signal CLK, the scan flip-flop circuit 10 and the scan flip-flop circuit 12 temporarily store the data value received at the second data input terminal SI respectively, and respectively output the previously stored data value to the scan flip-flop circuit (not shown in the figure) coupled to the data output Q. In other words, the plurality of data values of the test pattern STP are transmitted serially along the scan chain path. Before the end of the shift phase, the scan flip-flop circuit 10 and the scan flip-flop circuit 12 respectively store a corresponding data value of the data values of the test pattern STP.

In the capture phase, the scan enable signal sen has a second logic value. Initially, the timing exception domain 16 operates according to the data value temporarily stored in the scan flip-flop circuit 12. The at-speed domain 14 operates according to the data value temporarily stored in the scan flip-flop circuit 10, the data value temporarily stored in the scan flip-flop circuit 12 and the data value generated by the operation of the timing exception domain 16. Thereafter, in response to the triggering of at least one pulse of the clock signal CLK, the scan flip-flop circuit (not shown in the figure) coupled to the data output terminal of the at-speed domain 14 temporarily stores the data value generated by the operation of the at-speed domain 14. In addition, the scan flip-flop circuit 10 and the scan flip-flop circuit 12 also temporarily store the data values generated by the operation of the combinational logic circuit (not shown in the figure) coupled to the first data input terminal D, respectively.

After the capture phase, the circuitry 1 enters the shift phase again. The plurality of data values generated by the operation of the plurality of combinational logic circuits of circuitry 1 are serially transmitted along the scan chain path and are ultimately received by the automatic test equipment ATE. In this way, the automatic test equipment ATE can obtain the operating status of the plurality of combinational logic circuits of the circuitry 1 based on the plurality of received data values (i.e., the test output STR).

In the related technology, the scan test generally includes the tests for stuck-at faults and transition delay faults. In FIG. 1, the timing exception domain 16 is configured to have timing exception paths such as false path and multicycle path, so that an unknown or unexpected data value due to the transition of the scan flip-flop circuit 12 (e.g., from the stored logic “0” to the stored logic “1”, from the stored logic “1” to the stored logic “0”, etc.) can be generated during the transition delay fault test. At-speed domain 14 does not have this problem, but it may be affected by receiving the unknown data value generated by the timing exception domain 16, which further increases the number of test patterns, the test time, and the test cost. It should be noted that under the stuck-at fault test, it is not necessary to consider the problem of the timing exception domain 16 generating the unknown data value due to the transition of the scan flip-flop circuit 12.

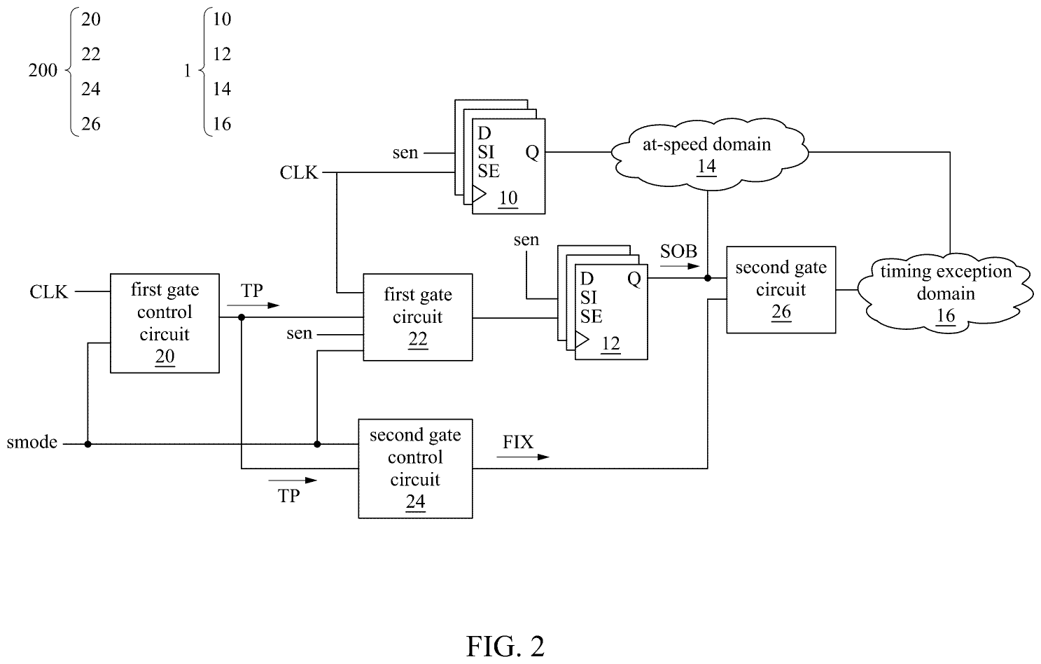

In view of this, the present disclosure provides a circuit that can solve the above problem, and it will be described in detail with reference to FIG. 2. Please refer to FIG. 2, which is a block diagram of a clock control circuit 200 applied to the circuitry 1 in FIG. 1 according to some embodiments of the present disclosure. In some embodiments, the clock control circuit 200 is configured to control the circuitry 1 and comprises a first gate control circuit 20, a first gate circuit 22, a second gate control circuit 24 and a second gate circuit 26.

In some embodiments, the first gate control circuit 20 is configured to receive the clock signal CLK and a scan mode signal smode, to be controlled by the scan mode signal smode, and to output a first control signal TP.

In some embodiments, the first gate circuit 22 is coupled to the first gate control circuit 20 and the scan flip-flop circuit 12 to receive the clock signal CLK, the first control signal TP, the scan enable signal sen and the scan mode signal smode, to be controlled by the first control signal TP, the scan enable signal sen and the scan mode signal smode, and to block or output the clock signal CLK to the scan flip-flop circuit 12.

In some embodiments, the second gate control circuit 24 is coupled to the first gate control circuit 20 to receive the first control signal TP and the scan mode signal smode, to be controlled by the scan mode signal smode, and to output a second control signal FIX.

In some embodiments, the second gate circuit 26 is coupled to the scan flip-flop circuit 12, the second gate control circuit 24 and the timing exception domain 16 to receive the second control signal FIX and an output signal SOB of the scan flip-flop circuit 12, to be controlled by the second control signal FIX, and to block or output the output signal SOB of the scan flip-flop circuit 12 to the timing exception domain 16.

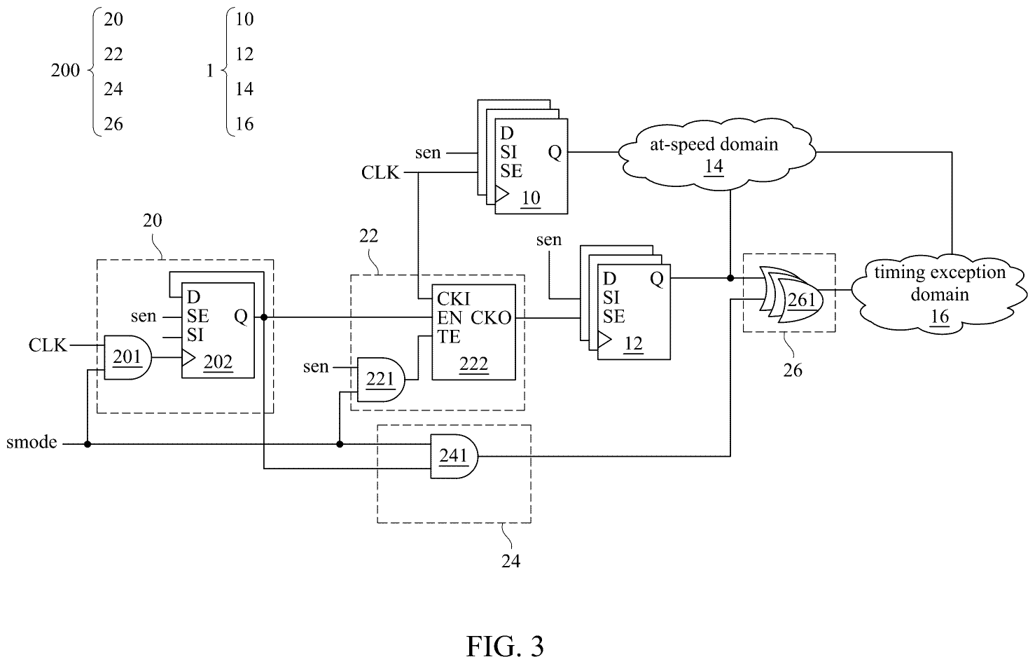

In the above embodiment, the scanning mode signal smode switches between a first logic value and a second logic value based on whether the circuitry 1 operates under the scan test. For example, when circuitry 1 operates under the scan test, the scan mode signal smode has the first logic value. When circuitry 1 does not operate under the scan test, the scan mode signal smode has the second logic value. Furthermore, when the scan mode signal smode has the second logic value, the circuitry 1 can operate in a function mode. The function mode is well known to those skilled in the art to which this disclosure belongs, and then it is not described in detail here. The description of the clock signal CLK and the scan enable signal sen can be referred to that of FIG. 1, and then it is therefore omitted here. In addition, the first control signal TP, the second control signal FIX and the output signal SOB will be described in detail in the following examples. The circuit structure of the first gate control circuit 20, the first gate circuit 22, the second gate control circuit 24 and the second gate circuit 26 will be described in detail with reference to FIG. 3.

Please refer to FIG. 3, which is a schematic diagram of the clock control circuit 200 in FIG. 2. In some embodiments, the first gate control circuit 20 comprises a logic circuit 201 and a switch control circuit 202. The logic circuit 201 can be implemented by an AND gate, and the switch control circuit 202 can be implemented by a scan flip-flop circuit. Thus, as shown in FIG. 3, the switch control circuit 202 also has a first data input terminal D, an input enable terminal SE, a second data input terminal SI, a clock input terminal (represented by “>” in FIG. 3) and a data output terminal Q. A first input terminal of the logic circuit 201 is configured to receive the clock signal CLK. A second input terminal of the logic circuit 201 is configured to receive the scan mode signal smode. An output terminal of the logic circuit 201 is coupled to the clock input terminal of the switch control circuit 202. The input enable terminal SE of the switch control circuit 202 is configured to receive the scan enable signal sen. The data output terminal Q of the switch control circuit 202 is coupled to the first data input D of the switch control circuit 202, the first gate circuit 22 and the second gate control circuit 24, and is configured to output the first control signal TP in FIG. 2. It should be understood that the second data input terminal SI of the switch control circuit 202 can be coupled to the data output terminal of at least one scan flip-flop circuit in the circuitry 1. In other words, the second data input SI of the switch control circuit 202 is coupled to the scan chain path (which can include the scan flip-flop circuit 10, the scan flip-flop circuit 12 and the other scan flip-flop circuits not shown) of the circuitry 1.

In some embodiments, the first gate circuit 22 comprises a logic circuit 221 and a switch circuit 222. A first input terminal of the logic circuit 221 is configured to receive the scan enable signal sen. A second input terminal of the logic circuit 221 is configured to receive the scan mode signal smode. A primary enable terminal TE of the switch circuit 222 is coupled to an output terminal of the logic circuit 221. A secondary enabling input EN of the switch circuit 222 is coupled to the data output terminal Q of the switch control circuit 202 and is configured to receive the first control signal TP in FIG. 2. The clock input terminal CKI of the switch circuit 222 is configured to receive the clock signal CLK. The clock output terminal CKO of the switch circuit 222 is coupled to the clock input terminal of the scan flip-flop circuit 12. In addition, the logic circuit 221 can be implemented by an AND gate, and the switch circuit 222 can be implemented by an integrated clock gating (IGC) circuit.

In some embodiments, the second gate control circuit 24 comprises a logic circuit 241. A first input terminal of the logic circuit 241 is configured to receive the scan mode signal smode. A second input terminal of the logic circuit 241 is coupled to the first gate control circuit 20. Furthermore, the second input terminal of the logic circuit 241 is coupled to the data output terminal Q of the switch control circuit 202 and is configured to receive the first control signal TP in FIG. 2. An output terminal of the logic circuit 241 is coupled to the second gate circuit 26 and is configured to output the second control signal FIX in FIG. 2 to the second gate circuit 26. Furthermore, the logic circuit 241 can be implemented by and AND gate.

In some embodiments, the second gate circuit 26 comprises one or more logic circuits 261. A first input terminal of the logic circuit 261 is coupled to the data output terminal Q of the scan flip-flop circuit 12 and is configured to receive the output signal SOB in FIG. 2. A second input terminal of the logic circuit 261 is coupled to the second gate control circuit 24. Furthermore, the second input terminal of logic circuit 261 is coupled to the output terminal of logic circuit 241 and is configured to receive the second control signal FIX in FIG. 2. An output terminal of logic circuit 261 is coupled to the timing exception domain 16. In addition, the logic circuit 261 can be implemented by an OR gate.

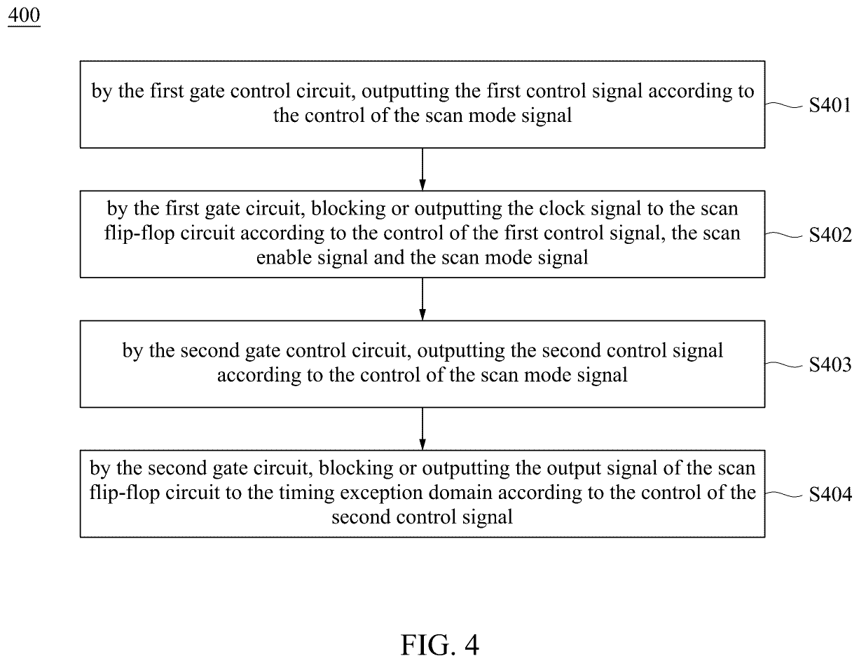

The operation of the clock control circuit 200 will be described in detail with a clock control method 400 as shown in FIG. 4. Please refer to FIG. 4, which is a flow chart of the clock control method 400 according to some embodiments of the present disclosure. In some embodiments, the clock control method 400 is applied to the clock control circuit 200. As shown in FIG. 4, the clock control method 400 comprises operations S401˜S404.

In operation S401, the first control signal TP is output by the first gate control circuit 20 according to the control of the scan mode signal smode.

In operation S402, the clock signal CLK is blocked or output to the scan flip-flop circuit 12 by the first gate circuit 22 according to the control of the first control signal TP, the scan enable signal sen and the scan mode signal smode.

In operation S403, the second control signal FIX is output by the second gate control circuit 24 according to the control of the scan mode signal smode.

In operation S404, the output signal SOB of the scan flip-flop circuit 12 is blocked or output by the second gate circuit 26 to the timing exception domain 16 according to the second control signal FIX.

Next, the operation of the clock control circuit 200 and the operation S401˜S404 of the clock control method 400 will be described with the conditions that the circuitry 1 operates in the scan test (i.e., stuck-at fault test, transition delay fault test, etc.) and in the function mode.

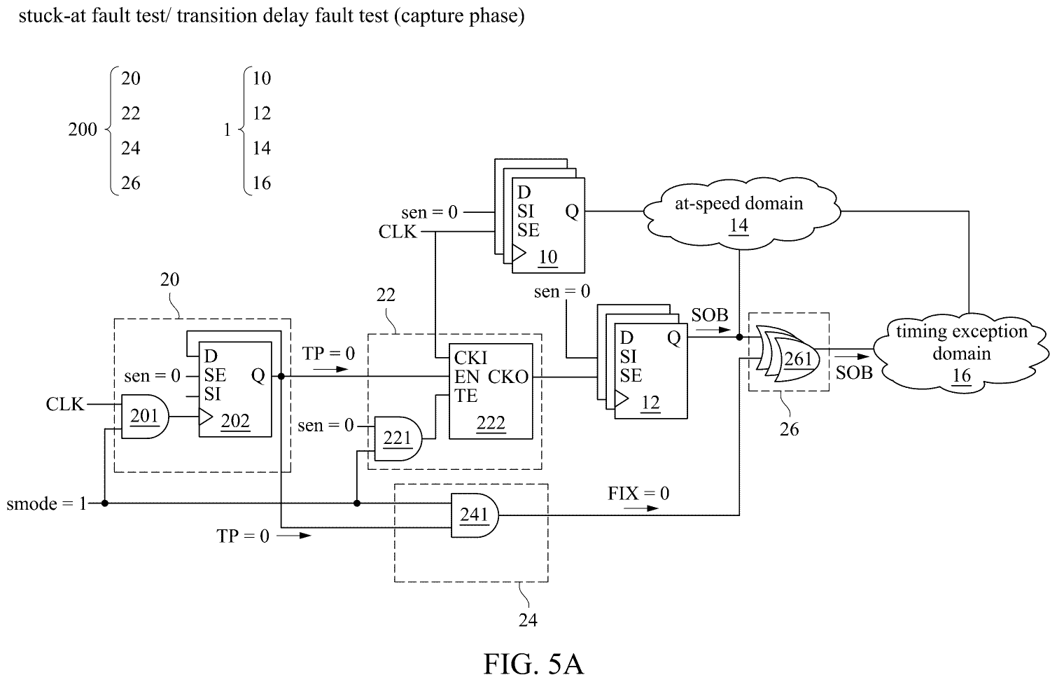

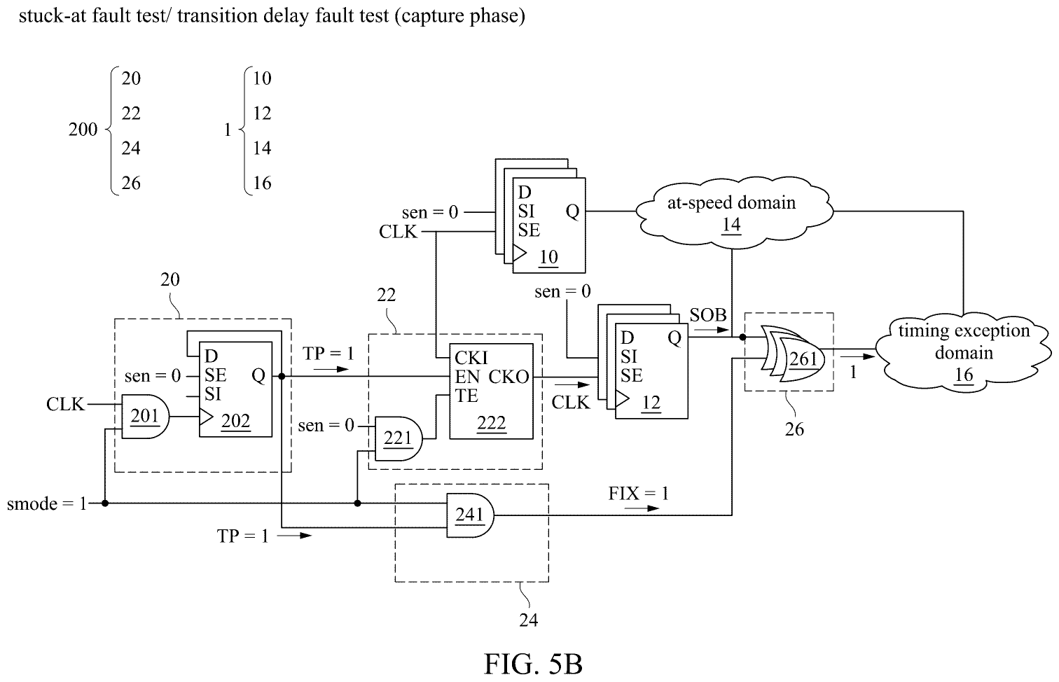

Please refer to FIGS. 5A and 5B, which are schematic diagrams of the operation of the clock control circuit 200 of the circuitry 1 in the capture phase of the stuck-at fault test or the transition delay fault test according to some embodiments of the present disclosure, respectively.

In the embodiment of FIG. 5A, the data value of the test pattern STP temporarily stored by the switch control circuit 202 after the shift phase is preset to logic “0”. Also, in the capture phase, as shown in FIG. 5A, the scan mode signal smode has the first logic value (i.e., logic “1”), and the scan enable signal sen has the second logic value (i.e., logic “0”).

Please see the first gate control circuit 20 in FIG. 5A. In some embodiments of the operation S401, the logic circuit 201 outputs the clock signal CLK to the clock input terminal of the switch control circuit 202 according to the scan mode signal smode with the first logic value. Therefore, the switch control circuit 202 responds to the triggering of at least one pulse of the clock signal CLK to temporarily store the data value of the logical “0” received at the first data input D and to output the data value of the logical “0” via the data output Q according to the scan enable signal sen. It can be seen that, in the capture phase, the first gate control circuit 20 outputs the first control signal TP having the second logic value (i.e., logic “0”) to the first gate circuit 22 and the second gate control circuit 24 according to the data value of logic “0” temporarily stored in the shift phase.

Please see the first gate circuit 22 in FIG. 5A. In some embodiments of the operation S402, the logic circuit 221 operates in the capture phase according to the scan enable signal sen and the scan mode signal smode to output a data value of logic “0” to the primary enable terminal TE of the switch circuit 222. On the condition that the primary enable terminal TE receives the data value of logic “O”, the switch circuit 222 will not output the clock signal CLK according to the first control signal TP with the second logic value received at the secondary enable terminal EN. It can be seen that the first gate circuit 22 blocks the transmission of the clock signal CLK to the clock input terminal of the scan flip-flop circuit 12. Therefore, the scan flip-flop circuit 12 does not undergo the transition triggered by at least one pulse of the clock signal CLK.

Please see the second gate control circuit 24 in FIG. 5A. In some embodiments of the operation S403, the logic circuit 241 can be considered a short circuit when the scan mode signal smode has a first logic value. Thus, the logic circuit 241 functions as to directly output the first control signal TP with the second logic value (i.e., logic “0”). It can be seen that the second gate control circuit 24 outputs the second control signal FIX with the second logic value (i.e., logic “0”) to the second gate circuit 26.

Please see the second gate circuit 26 in FIG. 5A. In some embodiments of the operation S404, the logic circuit 261 can be considered a short circuit when the second control signal FIX has the second logic value. Therefore, the logic circuit 261 functions as to directly output the output signal SOB of the scan flip-flop circuit 12. That is to say, the second gate circuit 26 transmits the output signal SOB of the scan flip-flop circuit 12 to the timing exception domain 16. Furthermore, since no transition occurs in the scan flip-flop circuit 12, the output signal SOB of the scan flip-flop circuit 12 has a fixed data value. Therefore, the timing exception domain 16 does not generate an unknown data value to the at-speed domain 14.

In the embodiment of FIG. 5B, the data value of the test pattern STP temporarily stored by the switch control circuit 202 after the shift phase is preset to logic “1”. Then, as shown in FIG. 5A, the circuitry 1 operates in the capture phase of the scan test.

Please see the first gate control circuit 20 in FIG. 5B. In some embodiments of the operation S401, the logic circuit 201 functions as to output clock signal CLK to the clock input terminal of the switch control circuit 202 according to the scan mode signal smode with the first logic value. Therefore, the switch control circuit 202 responds to the triggering of at least one pulse of the clock signal CLK, temporarily stores the data value of logic “1” received at the first data input D according to the scan enable signal sen, and outputs the data value of logic “1” via the data output Q. It can be seen that, in the capture phase, the first gate control circuit 20 outputs a first control signal TP with the first logic value (i.e., logic “1”) to the first gate circuit 22 and the second gate control circuit 24 according to the data value of logic “1” temporarily stored in the shift phase.

Please see the first gate circuit 22 in FIG. 5B. In some embodiments of the operation S402, the logic circuit 221 operates in the capture phase according to the scan enable signal sen and the scan mode signal smode to output a data value of logic “0” to the primary enable terminal TE of the switch circuit 222. On the condition that the primary enable terminal TE receives the data value of logic “O”, the switch circuit 222 outputs the clock signal CLK according to the first control signal TP with the first logic value received by the secondary enable terminal EN. It can be seen that the first gate circuit 22 provides the clock signal CLK to the clock input terminal of the scan flip-flop circuit 12. Therefore, the scan flip-flop circuit 12 is triggered by at least one pulse of the clock signal CLK and the transition may occur.

Please see the second gate control circuit 24 in FIG. 5B. In some embodiments of the operation S403, the logic circuit 241 can be considered a short circuit when the scan mode signal smode has the first logic value. Therefore, the logic circuit 241 functions as to directly output the first control signal TP with the first logic value (i.e., logic “1”). It can be seen that the second gate control circuit 24 outputs the second control signal FIX with the first logic value (i.e., logic “1”) to the second gate circuit 26.

Please see the second gate circuit 26 in FIG. 5B. In some embodiments of the operation S404, on the condition that the second control signal FIX has the first logic value, regardless of whether the output signal SOB of the scan flip-flop circuit 12 has the data value of logic “1” or logic “0”, the logic circuit 261 only outputs the data value of logic “1”. That is to say, the second gate circuit 26 only outputs a preset signal having the first logic value to the timing exception domain 16. Furthermore, although the transition may occur at the scan flip-flop circuit 12, the timing exception domain 16 does not generate the unknown data value to the at-speed domain 14 because it only receives the preset signal having the first logic value.

Furthermore, in the above embodiment, when the circuitry 1 operates in the shift phase of the scan test (i.e., the scan mode signal smode has a first logic value (i.e., logic “1”) and the scan enable signal sen has a first logic value (i.e., logic “1”)), the logic circuit 221 outputs the data value of logic “1” according to the scan enable signal sen and the scan mode signal smode. On the condition that the primary enable terminal TE receives the data value of logic “1”, regardless of whether the first control signal TP has the first logic value or the second logic value, the switch circuit 222 outputs the clock signal CLK. That is to say, the first gate circuit 22 provides the clock signal CLK to the clock input terminal of the scan flip-flop circuit 12. Thus, the scan flip-flop circuit 12 can be set to a corresponding data value of the plurality of data values of the test pattern STP.

As can be seen from the description of the embodiments in FIGS. 5A and 5B, the first gate control circuit 20 is configured to output the first control signal TP having the first logic value or the second logic value according to the test pattern STP when the scan mode signal smode has the first logic value (i.e., the scan test). The first gate circuit 22 is configured to block or output the clock signal CLK to the scan flip-flop circuit 12 according to the logic value of the first control signal TP when the scan mode signal smode has the first logic value and the scan enable signal sen has the second logic (i.e., the capture phase), and is configured to provide the clock signal CLK to the scan flip-flop circuit 12 when the scan mode signal smode has the first logic value and the scan enable signal sen has the first logic value (i.e., the shift phase). The second gate control circuit 24 is configured to output the second control signal FIX with the first logic value or the second logic value according to the logic value of the first control signal TP when the scan mode signal smode has the first logic value. That is to say, in the scan test, both the first control signal TP and the second control signal FIX switch between the first logic value and the second logic value according to the test pattern STP. In addition, the second gate circuit 26 is configured to output the preset signal with the first logic value to the timing exception domain 16 when the second control signal FIX has the first logic value, and to provide the output signal SOB to the timing exception domain 16 when the second control signal FIX has the second logic value.

It is should be noted that, as shown in FIGS. 5A and 5B, when the circuitry 1 operates in the capture phase of the scan test, the clock control circuit 200 always provide fixed data value (e.g., the output signal SOB of the scan flip-flop circuit 12 without transition, the preset signal with the first logic value, etc.) to the timing exception domain 16. In this way, the transition delay fault test for the circuitry 1 will not be affected by unknown data values, which can avoid the increases of the number of test patterns, the test time and the test costs. In addition, under a stuck-at fault test, since the second control signal FIX received by the second input terminal of the logic circuit 261 switches between the first logic value and the second logic value, the stuck-at-fault test can be further performed on the second input terminal of logic circuit 261 in addition to the stuck-at-1 fault test on the second input of logic circuit 261. Accordingly, the test coverage of the stuck-at fault test is greatly improved. Incidentally, if the second input terminal of the logic circuit 261 can only receive the second control signal FIX with a fixed logic value under a stuck-at fault test, it cannot perform the stuck-at-0 fault test on the second input terminal of the logic circuit 261.

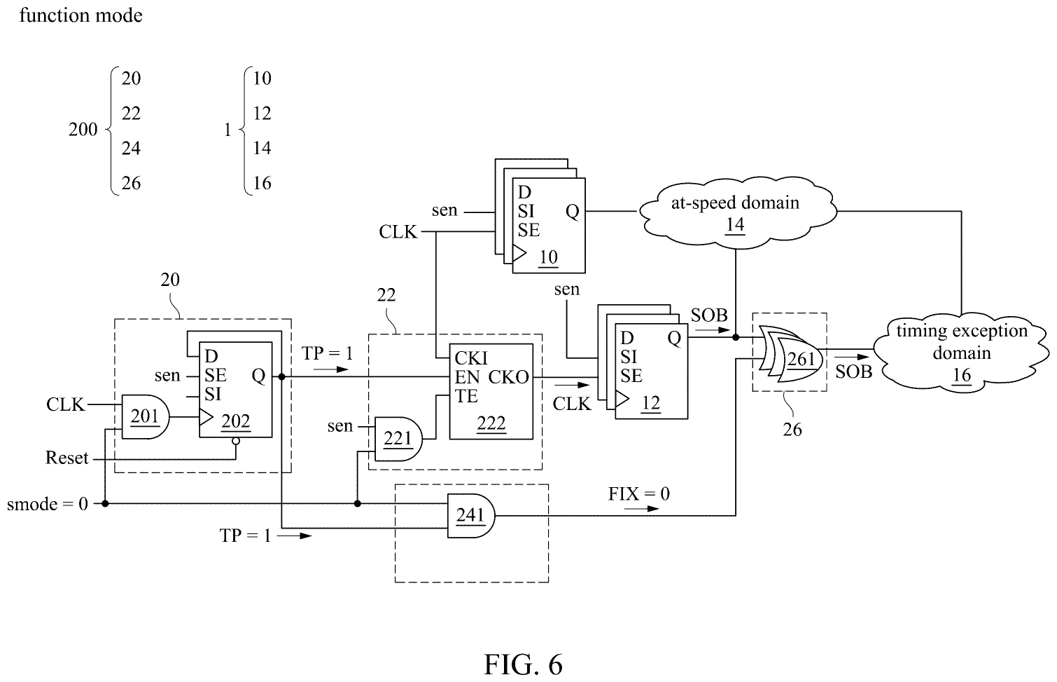

Please refer to FIG. 6, which is a schematic diagram of the operation of the clock control circuit 200 in the circuitry 1 in the functional mode according to some embodiments of the present disclosure. In the functional mode, the scan mode signal smode has the second logic value (i.e., logic “0”), as shown in FIG. 6.

Please see the first gate control circuit 20 in FIG. 6. In some embodiments, the switch control circuit 202 also receives a reset signal Reset. In some embodiments of the operation S401, on the condition that the scan mode signal smode has the second logic value, the switch control circuit 202 functions as not being able to be triggered by at least one pulse in the clock signal CLK, and being reset through the reset signal Reset to only output the first control signal TP having the first logic value (i.e., logic “1”).

Please see the first gate circuit 22 in FIG. 6. In some embodiments of the operation S402, the logic circuit 221 operates according to the scan enable signal sen and the scan mode signal smode to output the data value of logic “0” to the primary enable terminal TE of the switch circuit 222. On the condition that the primary enable terminal TE receives the data value of logic “0”, the switch circuit 222 outputs the clock signal CLK according to the first control signal TP with the first logic value received by the secondary enable terminal EN. It can be seen that the first gate circuit 22 provides the clock signal CLK to the clock input terminal of the scan flip-flop circuit 12.

Please see the second gate control circuit 24 in FIG. 6. In some embodiments of the operation S403, on the condition that the scan mode signal smode has the second logic value, the logic circuit 241 only outputs the data value of logic “0”. That is to say, the second gate control circuit 24 only outputs the second control signal FIX with the second logic value (i.e., logic “0”) to the second gate circuit 26.

Please see the second gate circuit 26 in FIG. 6. In some embodiments of the operation S404, the logic circuit 261 can be considered a short circuit when the second control signal FIX has the second logic value. Therefore, the logic circuit 261 functions as to directly output the output signal SOB of the scan flip-flop circuit 12. That is to say, the second gate circuit 26 transmits the output signal SOB of the scan flip-flop circuit 12 to the timing exception domain 16.

As can be seen from the description of the embodiment in FIG. 6, the first gate control circuit 20 is configured to output the first control signal TP with the first logic value by the control of the reset signal Reset when the scan mode signal smode has the second logic value. The first gate circuit 22 is configured to provide the clock signal CLK to the scan flip-flop circuit 12 when the first control signal TP has the first logic value and the scan mode signal smode has the second logic value. The second gate control circuit 24 is configured to output the second control signal FIX with the second logic value when the scan mode signal smode has the second logic value.

It should be noted that as shown in FIG. 6, when the circuitry 1 operates in the function mode, the clock control circuit 200 provides the clock signal CLK to the scan flip-flop circuit 12 and provides the output signal SOB of the scan flip-flop circuit 12 to the timing exception domain 16. In this way, the clock control circuit 200 does not affect the operation of the circuitry 1 in the function mode.

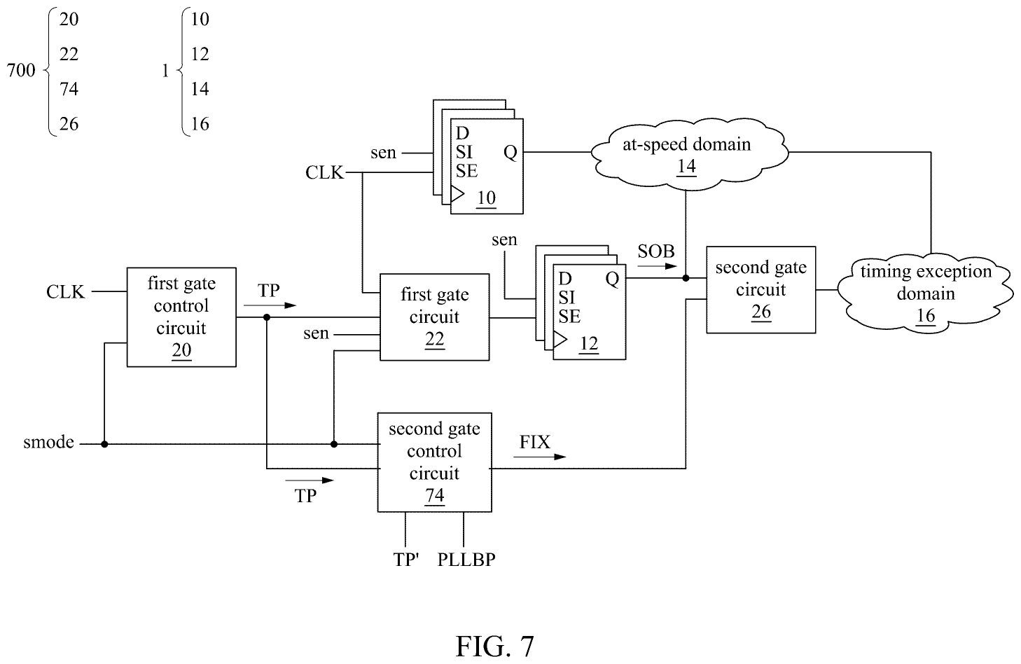

This disclosure also provides another clock control circuit 700 applied to the circuitry 1 in FIG. 1. Please refer to FIG. 7, which is a block diagram of the clock control circuit 700 according to some embodiments of this disclosure. In some embodiments, the second gate control circuit 24 in FIG. 2 is replaced by another second gate control circuit 74 to form the clock control circuit 700 as shown in FIG. 7.

As shown in FIG. 7, the second gate control circuit 74 is also configured to receive a test switching signal PLLBP and a third control signal TP′. In some embodiments, the third control signal TP′ can switch between the first logic value and the second logic value according to the test pattern STP under the scan test. In addition, the test switching signal PLLBP switches between the first logic value and the second logic value according to the type of the scan test. For example, the test switching signal PLLBP has the first logic value when the scan test is the stuck-at fault test. The test switching signal PLLBP has the second logic value when the scan test is the transition delay fault test.

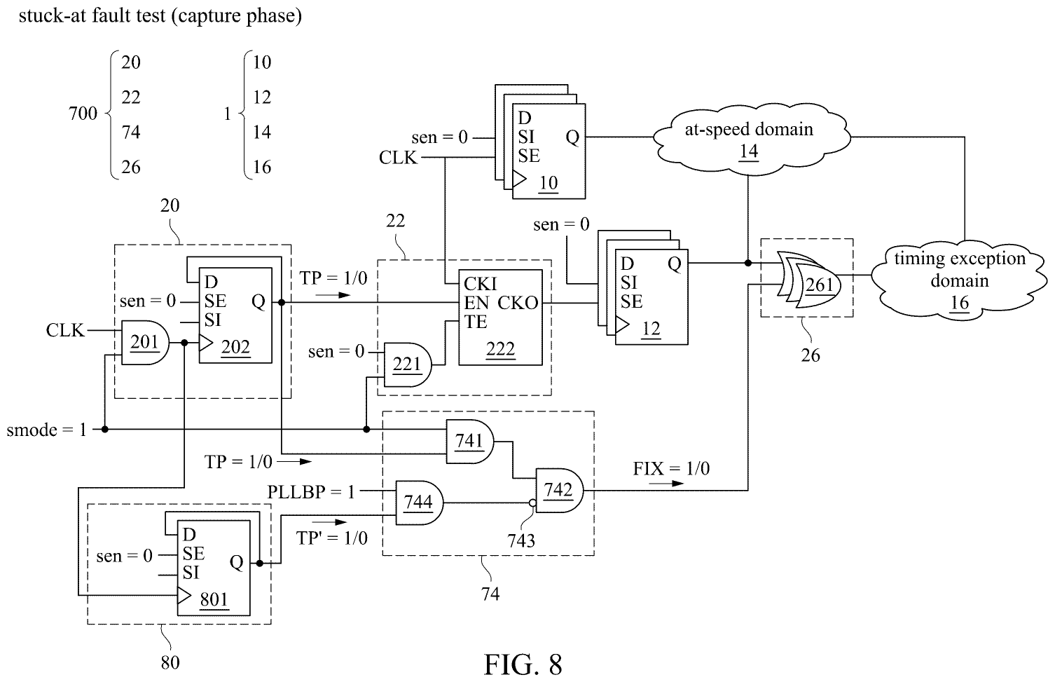

The circuit structure of the second gate control circuit 74 is described in detail with FIG. 8. FIG. 8 is a schematic diagram of the clock control circuit 700 in FIG. 7. In some embodiments, the second gate control circuit 74 comprises a logic circuit 741, a logic circuit 742, a logic circuit 743 and a logic circuit 744. A first input terminal of the logic circuit 741 is configured to receive the scan mode signal smode. A second input terminal of the logic circuit 741 is coupled to the first gate control circuit 20 and is configured to receive the first control signal TP. A first input terminal of the logic circuit 742 is coupled to an output terminal of the logic circuit 741. An output terminal of the logic circuit 742 is coupled to a second gate circuit 26 and is configured to output the second control signal FIX. An output terminal of the logic circuit 743 is coupled to a second input terminal of the logic circuit 742. A first input terminal of the logic circuit 744 is configured to receive the test switching signal PLLBP. A second input terminal of the logic circuit 744 is configured to receive third control signal TP′. An output terminal of the logic circuit 744 is coupled to an input terminal of the logic circuit 743. In addition, the logic circuit 741, the logic circuit 742 and the logic circuit 744 can be implemented by AND gates, and the logic circuit 743 can be implemented by a NOT gate.

In some embodiments, as shown in FIG. 8, in the capture phase of the stuck-at fault test, the first control signal TP may have the first logic value or the second logic value according to the test pattern STP, as described with reference to the embodiments of FIGS. 5A and 5B. It should be noted that the third control signal TP′ can switch between the first logic value and the second logic value according to the test pattern STP.

In the embodiment of FIG. 8, the third control signal TP′ is output by a signal generating circuit 80. In some embodiments, the signal generating circuit 80 includes a scan flip-flop circuit 801. A clock input terminal of the scan flip-flop circuit 801 is coupled to the output terminal of the logic circuit 201. An input enable terminal SE of the scan flip-flop circuit 801 is configured to receive the scan enable signal sen. A first data input terminal D of the scan flip-flop circuit 801 is coupled to a data output terminal Q of the scan flip-flop circuit 801 and the second input terminal of the logic circuit 744. In addition, a second data input terminal SI of the scan flip-flop circuit 801 can be coupled to the data output terminal of at least one scan flip-flop circuit in the circuitry 1 (i.e., coupled to the scan chain path of the circuitry 1).

The operation of the scan flip-flop circuit 801 is similar to the operation of the switch control circuit 202 in FIGS. 5A and 5B, so that it will not be described in detail here. In short, the signal generating circuit 80 can also output a third control signal TP′ having a first logic value or a second logic value according to the test pattern STP when the scan mode signal smode has a first logic value (i.e., scan test).

As shown in FIG. 8, when the electrical system 1 operates under the stuck-at fault test, the scan mode signal smode has the first logic value, and the test switching signal PLLBP has the first logic value. In the capture phase of the stuck-at fault test, the first control signal TP and the third control signal TP′ may respectively have the first logic value or the second logic value according to the test pattern STP. Accordingly, the second gate control circuit 74 will output the second control signal FIX with the first logic value or the second logic value according to the logic value of the first control signal TP and the logic value of the third control signal TP′. The logic values changes of the second control signal FIX are shown in Table 1 below.

TABLE 1

| smode | TP | PLLBP | TP′ | FIX |
|---|---|---|---|---|
| 1 | 0 | 1 | 0 | 0 |
| 1 | 0 | 1 | 1 | 0 |
| 1 | 1 | 1 | 0 | 1 |
| 1 | 1 | 1 | 1 | 0 |

As can be seen from Table 1, under the stuck-at fault test, the second control signal FIX output by the second gate control circuit 74 also functions as to switch between the first logic value and the second logic value according to the test pattern STP. Therefore, the stuck-at-1 fault test and the stuck-at-0 fault test can still be performed on the second input terminal of the logic circuit 261, so as to greatly improve the test coverage of the stuck-at fault test.

It should be understood that the structure and the operation of the first gate control circuit 20, the first gate circuit 22 and the second gate circuit 26 in FIGS. 7 and 8 are the same as or similar to those described in the embodiments of FIGS. 2-3, 5A-5B and 6, and therefore are omitted here.

When the circuitry 1 operates under the transition delay fault test, the scan mode signal smode has the first logic value, and the test switching signal PLLBP has the second logic value. In the second gate control circuit 74 of FIG. 8, the logic circuit 744 outputs the data value of logic “0” to the logic circuit 743, and the logic circuit 743 outputs the data value of logic “1” to the second input terminal of the logic circuit 742. Moreover, on the basis of the first logic value of the scan mode signal smode and the data value of logic “1” output by the logic circuit 743, the logic circuits 741 and 742 function as to directly output the first control signal TP. That is to say, the second gate control circuit 74 outputs the second control signal FIX with the first logic value or the second logic value according to the logic value of the first control signal TP.

In addition, when the circuitry 1 operates in the function mode, the scan mode signal smode has the second logic value. On the basis of the scan mode signal smode with the second logic value, the logical circuit 741, the logical circuit 742, the logical circuit 743 and the logical circuit 744 operate together and then ultimately generate the data value of logic “0”. That is to say, the second gate control circuit 74 only outputs the second control signal FIX with the second logic value.

Although the present invention has been described in considerable detail with reference to certain embodiments thereof, other embodiments are possible. Therefore, the spirit and scope of the appended claims should not be limited to the description of the embodiments contained herein.

What is claimed is:

1. A clock control circuit, configured for controlling a circuitry, the circuitry comprising a scan flip-flop circuit, an at-speed domain and a timing exception domain, the scan flip-flop circuit being configured to output data to the at-speed domain and the timing exception domain, the clock control circuit comprising:
a first gate control circuit, configured to be controlled by a scan mode signal, and configured to output a first control signal;
a first gate circuit, coupled to the first gate control circuit and the scan flip-flop circuit, the first gate circuit being configured to be controlled by the first control signal, a scan enable signal and the scan mode signal, and configured to block or output a clock signal to the scan flip-flop circuit;
a second gate control circuit, coupled to the first gate control circuit, the second gate control circuit being configured to be controlled by the scan mode signal and configured to output a second control signal, wherein when the scan mode signal has a first logic value, the second control signal switches between the first logic value and a second logic value different from the first logic value according to a test pattern for testing the circuitry; and
a second gate circuit, coupled to the scan flip-flop circuit, the second gate control circuit and the timing exception domain, the second gate circuit being configured to be controlled by the second control signal, and configured to block or output an output signal of the scan flip-flop circuit to the timing exception domain.

2. The clock control circuit according to claim 1, wherein the second gate control circuit is configured to output the second control signal having the first logic value or the second logic value according to the logic value of the first control signal when the scan mode signal has the first logic value,
wherein the first control signal switches between the first logic value and the second logic value when the scan mode signal has the first logic value.

3. The clock control circuit according to claim 1, wherein the second gate control circuit comprises a logic circuit, a first input terminal of the logic circuit is configured to receive the scan mode signal, a second input terminal of the logic circuit is coupled to the first gate control circuit and configured to receive the first control signal, and an output terminal of the logic circuit is coupled to the second gate circuit and configured to output the second control signal.

4. The clock control circuit according to claim 1, wherein the second gate control circuit is configured to receive a third control signal and a test switching signal, and configured to output the second control signal having the first logic value or the second logic value according to the logic value of the first control signal and the logic value of the third control signal when the scan mode signal and the test switching signal both have the first logic value,
wherein the first control signal and the third control signal both switch between the first logic value and the second logic value according to the test pattern when the scan mode signal has the first logic value.

5. The clock control circuit according to claim 4, wherein the second gate control circuit comprises:
a first logic circuit, wherein a first input terminal of the first logic circuit is configured to receive the scan mode signal, and a second input terminal of the first logic circuit is coupled to the first gate control circuit and configured to receive the first control signal;
a second logic circuit, wherein a first input terminal of the second logic circuit is coupled to an output terminal of the first logic circuit, and an output terminal of the second logic circuit is coupled to the second gate circuit and configured to output the second control signal;
a third logic circuit, wherein an output terminal of the third logic circuit is coupled to a second input terminal of the second logic circuit; and
a fourth logic circuit, wherein a first input terminal of the fourth logic circuit is configured to receive the test switching signal, a second input terminal of the fourth logic circuit is configured to receive a third control signal, and an output terminal of the fourth logic circuit is coupled to an input terminal of the third logic circuit.

6. The clock control circuit according to claim 4, wherein the second gate control circuit is configured to output the second control signal having the first logic value or the second logic value according to the logic value of the first control signal when the scan mode signal has the first logic value and the test switching signal has the second logic value.

7. The clock control circuit according to claim 1, wherein the second gate control circuit is configured to output the second control signal having the second logic value when the scan mode signal has the second logic value.

8. The clock control circuit according to claim 1, wherein the first gate circuit is configured to provide the clock signal to the scan flip-flop circuit when the first control signal has the first logic value and the scan mode signal has the second logic value.

9. The clock control circuit according to claim 1, wherein the first gate circuit is configured to provide the clock signal to the scan flip-flop circuit when the scan mode signal has the first logic value and the scan enable signal has the first logic value.

10. The clock control circuit according to claim 1, wherein the first gate circuit is configured to block or output the clock signal to the scan flip-flop circuit according to the logic value of the first control signal when the scan mode signal has the first logic value and the scan enable signal has the second logic value.

11. The clock control circuit according to claim 1, wherein the first gate circuit comprises:
a logic circuit, wherein a first input terminal of the logic circuit is configured to receive the scan enable signal, and a second input terminal of the logic circuit is configured to receive the scan mode signal; and
a switch circuit, wherein a clock input terminal of the switch circuit is configured to receive the clock signal, a primary enable terminal of the switch circuit is coupled to an output terminal of the logic circuit, a secondary enable terminal of the switch circuit is configured to receive the first control signal, and a clock output terminal of the switch circuit is coupled to a clock input terminal of the scan flip-flop circuit.

12. The clock control circuit according to claim 1, wherein the second gate circuit is configured to output a preset signal having the first logic value to the timing exception domain when the second control signal has the first logic value,
wherein the second gate circuit is configured to provide the output signal to the timing exception domain when the second control signal has the second logic value.

13. The clock control circuit according to claim 1, wherein the second gate circuit comprises a logic circuit, a first input terminal of the logic circuit is coupled to a data output terminal of the scan flip-flop circuit and configured to receive the output signal, a second input terminal of the logic circuit is coupled to the second gate control circuit and configured to receive the second control signal, and an output terminal of the logic circuit is coupled to the timing exception domain.

14. The clock control circuit according to claim 1, wherein the first gate control circuit is configured to output the first control signal having the first logic value or the second logic value according to the test pattern when the scan mode signal has the first logic value,
wherein the first gate control circuit is configured to be controlled by a reset signal to output the first control signal having the first logic value when the scan mode signal has the second logic value.

15. The clock control circuit according to claim 1, wherein the first gate control circuit comprises:
a logic circuit, wherein a first input terminal of the logic circuit is configured to receive the clock signal, and a second input terminal is configured to receive the scan mode signal; and
a switch control circuit, configured to receive a reset signal and the scan enable signal, wherein a clock input terminal of the switch control circuit is coupled to an output terminal of the logic circuit, a data output terminal of the switch control circuit is coupled to the first gate circuit, the second gate control circuit and a first data input terminal of the switch control circuit, and a second data input terminal of the switch control circuit is coupled to a scan chain path of the circuitry, wherein the scan chain path comprises the scan flip-flop circuit.

16. A clock control method for a circuitry, wherein the circuitry comprises a scan flip-flop circuit, an at-speed domain and a timing exception domain, the scan flip-flop circuit is configured to output data to the at-speed domain and the timing exception domain, and the clock control method comprises:
by a first gate control circuit, outputting a first control signal according to the control of a scan mode signal;
by a first gate circuit coupled to the first gate control circuit and the scan flip-flop circuit, blocking or outputting a clock signal to the scan flip-flop circuit according to the control of the first control signal, a scan enable signal and the scan mode signal;
by a second gate control circuit coupled to the first gate control circuit, outputting a second control signal according to the control of the scan mode signal, wherein when the circuitry operates in a capture phase of a scan test, the second control signal switches between a first logic value and a second logic value according to a test pattern for testing the circuitry; and
by a second gate circuit coupled to the scan flip-flop circuit, the second gate control circuit and the timing exception domain, blocking or outputting an output signal of the scan flip-flop circuit to the timing exception domain according to the control of the second control signal.

17. The clock control method according to claim 16, wherein the step of by the second gate control circuit, outputting the second control signal according to the control of the scan mode signal comprises:
by the second gate control circuit, outputting the second control signal having the first logic value or the second logic value according to the logic value of the first control signal when the scan mode signal has the first logic value, wherein the first control signal switches between the first logic value and the second logic value according to the test pattern.

18. The clock control method according to claim 16, wherein the step of by the second gate control circuit, outputting the second control signal according to the control of the scan mode signal comprises:
by the second gate control circuit, outputting the second control signal having the first logic value or the second logic value according to the logic value of the first control signal and the logic value of a third control signal when the scan mode signal and a test switching signal both have the first logic value, wherein the first control signal and the third control signal both switch between the first logic value and the second logic value according to the test pattern, and the test switching signal and the third control signal are received by the second gate control circuit.

19. The clock control method according to claim 18, wherein the step of by the second gate control circuit, outputting the second control signal according to the control of the scan mode signal comprises:
by the second gate control circuit, outputting the second control signal having the first logic value or the second logic value according to the logic value of the first control signal when the scan mode signal has the first logic value and the test switching signal has the second logic value.

20. The clock control method according to claim 16, wherein the step of by the second gate control circuit, outputting the second control signal according to the control of the scan mode signal comprises:
by the second gate control circuit, outputting the second control signal having the second logic value when the scan mode signal has the second logic value.
